(19) United States
(12) Patent Application Publication
(10) Pub. No.: US 2025/0202477 A1
(43) Pub. Date: Jun. 19, 2025

(54) A SOLID STATE SWITCH

(71) Applicant: Analog Devices International Unlimited Company, Co. Limerick (IE)

(72) Inventors: Jofrey Santillan, Limerick (IE); Declan McDonagh, Limerick (IE); David Aherne, Limerick (IE)

(73) Assignee: Analog Devices International Unlimited Company, Co. Limerick (IE)

(21) Appl. No.: 18/524,470

(22) PCT Filed: Aug. 30, 2022
(86) PCT No.: PCT/EP2022/074031

§ 371 Date: Nov. 30, 2023

(51) Int. Cl. H03K 17/687

(52) U.S. Cl. CPC H03K 17/687

(57) ABSTRACT

A solid state switch, comprising a first metal-oxide-semiconductor field-effect transistor (MOSFET) comprising: a drain terminal, a source terminal, and a gate terminal. The MOSFET is configured to be switched between an on-state and an off-state. The solid state switch also comprises a second MOSFET in series with the first MOSFET and a buffer with an output terminal and an input terminal. The second MOSFET has a gate terminal, a drain terminal, and a source terminal. The drain terminal of the first MOSFET is connected to the source terminal of the second MOSFET. The input terminal is coupled to the drain terminal of the second MOSFET. At least one of: the first MOSFET has an isolation terminal and the output terminal of the buffer is coupled to the isolation terminal of the first MOSFET; and, the second MOSFET has an isolation terminal and the output terminal of the buffer is coupled to the isolation terminal of the second MOSFET.

### CROSS REFERENCE TO RELATED PATENT APPLICATIONS

The present application is a U.S. 371 National Stage of PCT Patent Application No. PCT/EP2022/074031, entitled “A SOLID STATE SWITCH”, naming as inventors, Jofrey Santillan, Declan McDonagh, and David Aherne, and filed Aug. 30, 2022, which application is hereby incorporated by reference in its entirety.

### FIELD

This application relates to compensating for capacitance and leakage in a semiconductor switch (i.e. a solid state switch). Specifically, a metal-oxide-semiconductor field-effect-transistor (MOSFET or MOS), e.g., a high voltage MOS, such as a diffusion metal oxide semiconductor field effect transistor (DMOS).

### BACKGROUND

Solid state switches may be used with components such as, a precision measurement apparatus, and high voltage automated test equipment. A solid state switch can have an associated leakage and capacitance which affects the results at a precision measurement apparatus. For example, a large leakage current can reduce power efficiency and reduces the accuracy of component measurements connected via a solid state switch. Leakage reduction herein refers to reducing the actual leakage in a solid state switch. In addition, a large capacitance solid state switch can limit the speed of high frequency AC components connected via the solid state switch and reduce the accuracy of component measurements.

### SUMMARY OF DISCLOSURE

The present disclosure provides a solid state switch with a reduced capacitance at the drain terminal of a MOSFET and optionally with a reduced leakage current. Such solid state switches are suitable for use with AC voltage precision measurement apparatuses and AC high voltage automated test equipment.

According to a first aspect there is provided a solid state switch, comprising: a first metal-oxide-semiconductor field-effect transistor, MOSFET, comprising: a drain terminal, a source terminal, and a gate terminal, and configured to be switched between an on-state and an off-state; a second MOSFET in series with the first MOSFET, wherein the second MOSFET has a gate terminal, a drain terminal, and a source terminal, and wherein the drain terminal of the first MOSFET is connected to the source terminal of the second MOSFET; and a buffer comprising: an output terminal; and, an input terminal coupled to the drain terminal of the second MOSFET, wherein at least one of: the first MOSFET comprises an isolation terminal and the output terminal of the buffer is coupled to the isolation terminal of the first MOSFET; and the second MOSFET comprises an isolation terminal and the output terminal of the buffer is coupled to the isolation terminal of the second MOSFET. The second MOSFET may be configured to be switched between an on-state and an off-state.

The second MOSFET and the buffer may form a circuit which may be configured to isolate a parasitic capacitance of the first MOSFET from the drain terminal of the second MOSFET so as to reduce capacitance at the drain terminal of the first MOSFET. The circuit may be configured to isolate a parasitic capacitance (and leakage) from the first MOSFET's source/drain signal path (e.g., to reduce capacitance (and leakage) at the drain terminal of the MOS device).

The first aspect allows for a reduction in capacitance and may provide for a reduction in current leakage (also called leakage). It may also extend the operating frequency range of the solid state switch when compared to a MOSFET configured as a switch. If the buffer output terminal is coupled to an isolation terminal of the second MOSFET alone, then a reduction in the OFF capacitance/leakage can be achieved. If the buffer output terminal is coupled to an isolation terminal of the first MOSFET alone, then a reduction in the capacitance/leakage can be achieved. If the buffer output terminal is coupled to an isolation terminal of the first and second MOSFET, then a greater reduction in the capacitance/leakage can be achieved.

The buffer may be a unity gain buffer (UGB), a voltage follower, or a cascade complementary source follower.

If the buffer is a UGB, then the UGB may be arranged to reduce leakage at the drain terminal of the first MOSFET because a UGB has a very small voltage difference between its input voltage and its output voltage. A reduced leakage can result in improved power efficiency and accuracy of component measurements connected via the solid state switch.

The first MOSFET may be a high voltage MOSFET, and the second MOSFET may be an isolated 5V MOSFET.

When the first MOSFET is in the off-state, the buffer may be configured to be coupled in parallel with the second MOSFET between its drain and source terminals.

The first MOSFET may comprise an isolation terminal. The output terminal of the buffer may be coupled to the isolation terminal of the second MOSFET.

When the first MOSFET is in the on-state, the output terminal of the buffer may be further coupled to the gate terminal of the second MOSFET so as to latch the second MOSFET in an on-state.

The solid state switch may further comprise a substrate layer. The parasitic diode of the first MOSFET may be between the substrate layer and the isolation layer of the first MOSFET, and/or wherein the parasitic diode of the second MOSFET may be between the substrate layer and the isolation layer of the second MOSFET.

The first and/or second MOSFET may be a Diffusion MOSFET (DMOS).

The first and/or second MOSFET may be a Lateral Double-Diffusion MOSFET (LDMOS).

The first MOSFET may be a first DMOS. The solid state switch may further comprise a bi-directional DMOS switch comprising the first DMOS and a second DMOS. The second DMOS may comprise a gate terminal, a drain terminal, and a source terminal. The source terminal of the second DMOS may be coupled to the source terminal of the first DMOS.

The bi-directional DMOS switch may be a bi-directional Lateral Double-Diffusion MOSFET (LDMOS) switch. The first DMOS transistor may be an LDMOS and the second DMOS transistor may be an LDMOS.

The solid state switch may be a T-gate switch comprising the first MOSFET in parallel with a first-type DMOS. The first MOSFET may be a second-type DMOS. The first-type may be n-type or p-type. The second-type may be p-type or n-type. The first type may be different to the second type.

The solid state switch may further comprise a third MOSFET. The third MOSFET may be at least one of the second DMOS and the first-type DMOS. The solid state switch may further comprise: a fourth MOSFET in series with the third MOSFET. The fourth MOSFET may have a gate terminal, a drain terminal, and a source terminal. The drain terminal of the third MOSFET may be connected to the source terminal of the fourth MOSFET. The third MOSFET may comprise an isolation terminal and the output terminal of the buffer may be coupled to the isolation terminal of the third MOSFET. The fourth MOSFET may comprise an isolation terminal and the output terminal of the buffer may be coupled to the isolation terminal of the fourth MOSFET.

The buffer may be a first buffer, and the solid state switch may further comprise a third MOSFET, a fourth MOSFET, and a second buffer. The third MOSFET may be at least one of the second DMOS and the first-type DMOS. The fourth MOSFET may be in series with the third MOSFET. The fourth MOSFET may have a gate terminal, a drain terminal, and a source terminal. The drain terminal of the third MOSFET may be connected to the source terminal of the fourth MOSFET. The second buffer may comprise an output terminal and an input terminal coupled to the drain terminal of the fourth MOSFET. The third MOSFET may comprise an isolation terminal and the output terminal of the second buffer may be coupled to the isolation terminal of the third MOSFET. The fourth MOSFET may comprise an isolation terminal and the output terminal of the second buffer may be coupled to the isolation terminal of the fourth MOSFET.

A parasitic diode of the third MOSFET may be between the substrate layer and the isolation layer of the third MOSFET.

A parasitic diode of the fourth MOSFET may be between the substrate layer and the isolation layer of the fourth MOSFET.

The third MOSFET may be a DMOS or a Lateral Double-Diffusion MOSFET (LDMOS).

The fourth MOSFET may be a DMOS or a LDMOS.

According to a second aspect there is provided a solid state switch, comprising: a first metal-oxide-semiconductor field-effect transistor, MOSFET, comprising: a drain terminal, a source terminal, and a gate terminal, and configured to be switched between an on-state and an off-state; a second MOSFET in series with the first MOSFET, wherein the second MOSFET has a gate terminal, a drain terminal, and a source terminal, wherein the drain terminal of the first MOSFET is coupled to the source terminal of the second MOSFET; and a buffer comprising: an output terminal coupled to the source terminal of the second MOSFET when the first MOSFET is in the off-state; and an input terminal coupled to the drain terminal of the second MOSFET.

Optionally, at least one of: the first MOSFET may comprise an isolation terminal and the output terminal of the buffer may be further coupled to the isolation terminal of the first MOSFET; and the second MOSFET may comprise an isolation terminal and the output terminal of the buffer may be coupled to the isolation terminal of the second MOSFET.

According to a third aspect there is provided a circuit comprising: a MOSFET, wherein the MOSFET has a gate terminal, a drain terminal, and a source terminal; and, a buffer comprising: an output terminal; and an input terminal coupled to the drain terminal of the MOSFET. The MOSFET is configured to be coupled to another MOSFET in series such that the source terminal of the MOSFET is coupled to the drain terminal of the other MOSFET. The output terminal of the buffer is configured to be coupled to an isolation terminal of another MOSFET. The output terminal of the buffer may be configured to be coupled to an isolation terminal of the other MOSFET and/or the MOSFET comprises an isolation terminal and the output terminal of the buffer is coupled to the isolation terminal of the MOSFET.

Optional features of the first aspect may be applied to the second aspect and/or the third aspect.

### FIGURES

FIG. 1 illustrates a design of a NLDMOS switch.

FIG. 2 illustrates a bi-directional NLDMOS switch comprising a first NLDMOS and a second NLDMOS in series.

FIG. 3a illustrates the LDNMOS of FIGS. 1 and 2 with a parasitic drain-substrate capacitor (C_{dsub}) shown.

FIG. 3b illustrates the LDNMOS of FIGS. 1 and 2 with the parasitic drain-substrate capacitor (C_{dsub}), a parasitic source-drain capacitor (C_{sd}), a parasitic gate-source capacitor (C_{gs}), and a parasitic gate-drain capacitor (C_{gd}).

FIG. 4 illustrates an example of a semiconductor structure of an LDMOS transistor, specifically an NLDMOS.

FIG. 5 illustrates a solid state switch comprising a NLDMOS coupled in series to a circuit comprising a MOSFET and a buffer.

FIG. 6a illustrates the solid state switch of FIG. 5 with a parasitic drain-substrate capacitor (C_{dsub}) of the NLDMOS and the MOSFET.

FIG. 6b illustrates the solid state switch of FIG. 5 with the parasitic drain-substrate capacitor (C_{dsub}) of the NLDMOS and the MOSFET, and a parasitic source-drain capacitor (C_{sd}), a parasitic gate-source capacitor (C_{gs}), and a parasitic gate-drain capacitor (C_{gd}) of the MOSFET.

FIG. 7a illustrates a bi-directional solid state switch with a circuit for unidirectional capacitance (and leakage) reduction.

FIG. 7b illustrates a bi-directional solid state switch with a circuit for bi-directional capacitance (and leakage) reduction.

FIG. 8 illustrates a bi-directional solid state T-gate switch with unidirectional capacitance (and leakage) reduction.

FIG. 9 illustrates a bi-directional high voltage (i.e. 10V or higher) solid state switch with low voltage (i.e., 5V or lower) unidirectional capacitance (and leakage) reduction.

FIG. 10 illustrates a bi-directional high voltage (i.e. 10V or higher) solid state T-gate switch with low voltage (i.e., 5V or lower) unidirectional capacitance (and leakage) reduction.

FIG. 11 illustrates a graph of an on-capacitance in a solid state switch based on experimental results.

FIG. 12 illustrates a graph of an off-capacitance in a solid state switch based on experimental results.

FIG. 13 illustrates a graph of an on-leakage in a solid state switch based on experimental results.

FIG. 14 illustrates a graph of an off-leakage in a solid state switch based on experimental results.

### DETAILED DESCRIPTION

A metal-oxide-semiconductor field-effect-transistor (MOSFET or MOS) device when configured to function as a switch is susceptible to parasitic capacitance and current leakage which can negatively impact measurement performance of equipment connected via said MOS device. To overcome the impact of parasitic capacitance and current leakage, additional circuitry can be coupled to the MOS device configured to function as a switch. All types of MOS devices (e.g., Diffusion MOSs (DMOSs), Lateral DMOSs (LDMOSs), vertical DMOSs (VDMOSs), etc.) can benefit from the additional circuitry. For example, the MOS devices described below are LDMOS devices configured to function as switches. In addition, the LDMOS devices may be lateral doubly diffused MOS devices. A DMOS device may imply a high-voltage device. For example, greater than 5V, or, greater than/equal to 10V, can be high-voltage.

As a brief non-limiting overview of the invention, a new MOS based switch for use in/with high voltage precision instruments is provided. The new MOS based switch can enable at least capacitance reduction/elimination from the signal path via the MOS based switch (and can also reduce/eliminate current leakage from the signal path via the MOS based switch). The new MOS based switch can comprise a MOS device coupled to another MOS device in series and a buffer coupled to an isolation terminal (e.g., buried layer terminal) of the MOS device to isolate a parasitic capacitance (and leakage) from the MOS device's source/drain signal path (e.g., to reduce capacitance (and leakage) at the drain terminal of the MOS device).

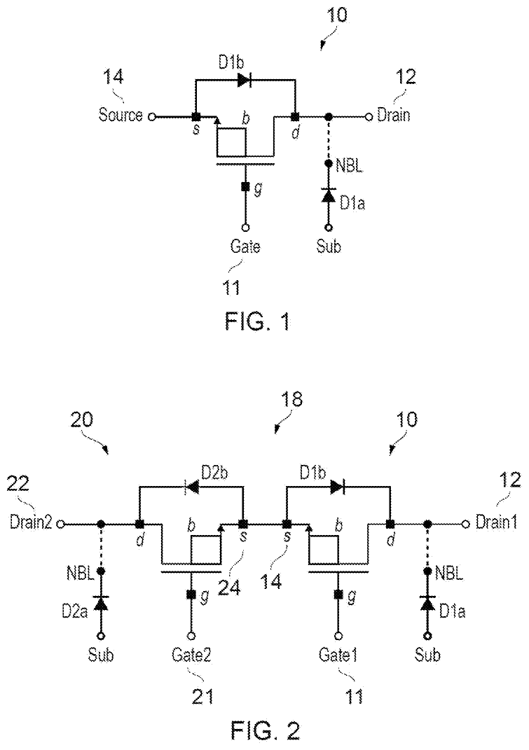

FIG. 1 shows an n-type LDMOS 10 (i.e., NLDMOS 10) with its parasitic diodes D1a and D1b. The parasitic diodes D1a and D1b of the NLDMOS 10 result from the fabrication process and are present in all types of DMOS switches. The parasitic diode D1a (between the substrate and an isolation layer, e.g. an N-type buried layer (NBL)) of the NLDMOS 10 is also present in MOSFET switches.

NLDMOS 10 comprises a gate terminal 11, a drain terminal 12, and a source terminal 14. D1a is formed between the substrate and the isolation layer, such as an NBL in FIG. 1. The NBL is coupled to a NBL terminal, which may be accessible to a circuit designer. The NBL terminal may typically be shorted to the drain terminal 12 for normal operation, which may reduce noise from the substrate. This may be achieved by externally coupling the NBL terminal to the drain terminal 12 or may be achieved by an internal connection of the NBL to the drain. D1b is formed between the source and drain of the NLDMOS 10. The parasitic diodes D1a and D1b are formed between P-type and N-type material of the NLDMOS 10.

A P-type LDMOS (PLDMOS) (or other p-type MOS switch) could be described similarly.

LDMOS devices are suitable for use in high voltage applications and may have source and channel regions formed using a double diffusion process. As a result of the fabrication process, the NLDMOS 10 is a uni-directional solid state switch and the parasitic diodes D1a and D1b are formed between high voltage P-type and N-type material. For example, when gate terminal 11 of the (uni-directional) NLDMOS switch 10 receives an ‘OFF’ signal, current may still flow from source terminal 14 to drain terminal 12 via the (forward biased) parasitic diode D1b.

FIG. 2 shows a bi-directional NLDMOS switch 18 comprising a first NLDMOS 10 and a second NLDMOS 20 in series. The second NLDMOS 20 comprises a gate terminal 21, a drain terminal 22, and a source terminal 24. The second NLDMOS 20 can be identical to the first NLDMOS 10. The source terminal 14 of the first NLDMOS 10 is coupled to a source terminal 24 of the second NLDMOS 20. The bi-directional NLDMOS switch 18 is arranged to, when ‘OFF’, block current flow in both directions: from the drain terminal 22 of the second NLDMOS 20 to the drain terminal 12 of the first NLDMOS 10; and from the drain terminal 12 of the first NLDMOS 10 to the drain terminal 22 of the second NLDMOS 20. To turn the first and second LDMOSs 10, 20 ‘OFF’, the gate-source voltage (Vgs) (between the gate terminals 11, 21 of the first and second LDMOSs 10, 20 and the source terminals 14, 24) is less than the threshold voltage (Vt), e.g., 0V. For example, the first and second LDMOSs 10, 20 may be turned ‘OFF’ by coupling gate terminals 11, 21 to source terminals 14, 24, or, by coupling both gate terminals 11, 21 and source terminals 14, 24 to the substrate (i.e., 0V).

If the voltage at the drain terminal 22 of the second NLDMOS 20 is greater than the voltage at the drain terminal 12 of the first NLDMOS 10, when both of the first and second NLDMOSs 10, 20 are ‘ON’, then the first and second NLDMOSs 10, 20 can allow current to flow from the drain terminal 22 of the second NLDMOS 20 to the drain terminal 12 of the first NLDMOS 12. When both of the first and second NLDMOSs 10, 20 are ‘OFF’, the second NLDMOS 20 blocks current flow from the drain terminal 22 to the source terminal 24 of the second NLDMOS 20 because the channel of the second NLDMOS 20 is pinched off and a parasitic diode D2b of the second NLDMOS 20 is reverse biased.

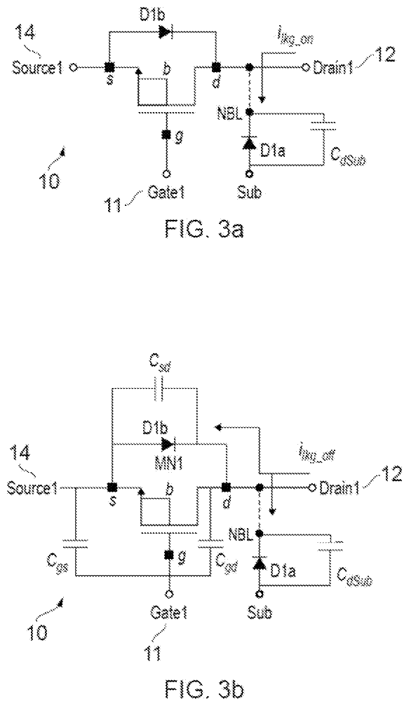

FIG. 3a shows the NLDMOS 10 of FIGS. 1 and 2 with a parasitic drain-substrate capacitor (C_{dsub}) shown. Alternatively, the NLDMOS 10 may be any type of MOS. The parasitic components shown in FIG. 3a are the dominant parasitic components when the NLDMOS 10 is switched ‘ON’.

When the NLDMOS 10 is in the on-state the drain/source voltage can be any value usually between the power supplies (e.g., Vcc and Vee). If the NLDMOS 10 is switched ‘ON’, the voltage difference between the source terminal 14 and the drain terminal 12 is approximately 0V (assuming a negligible/low ON-resistance). There can be a large voltage differential across the parasitic diode D1a and the C_{dsub} as the substrate may be connected to 0V or the most negative supply (e.g., Vee). The large voltage differential across the parasitic diode D1a causes: a leakage current i_{lkg_on} through the reverse biased parasitic diode D1a; and the associated C_{dsub}. The leakage current i_{lkg_on} reduces power efficiency and reduces the accuracy of component measurements connected via the NLDMOS 10. The C_{dsub} reduces the accuracy of component measurements connected via the NLDMOS 10.

FIG. 3b shows the NLDMOS 10 of FIGS. 1 and 2 with the parasitic drain-substrate capacitor (C_{dsub}), a parasitic source-drain capacitor (C_{sd}), a parasitic gate-source capacitor (C_{gs}), and a parasitic gate-drain capacitor (C_{gd}). The parasitic components shown in FIG. 3b are the dominant parasitic components when the NLDMOS 10 is switched ‘OFF’ and the voltage at the drain 12 is greater than the voltage at the source 14.

If the NLDMOS 10 is switched ‘OFF’ and the voltage at the drain 12 is greater than the voltage at the source 14, then there is a large voltage differential across the parasitic diode D1a, the C_{dsub}, the parasitic diode D1b, the C_{sd}, the C_{gd} and potentially C_{gs} (depending on the voltage difference between the gate 11 and the source 14). The large voltage differential across the parasitic diodes D1a and D1b causes: a leakage current i_{lkg_off} through the reverse biased parasitic diodes D1a and D1b; and the C_{dsub}, the C_{sd}, the C_{gd}, and potentially the C_{gs}. The leakage current i_{lkg_off} reduces power efficiency and reduces the accuracy of component measurements connected via the NLDMOS 10.

The C_{dsub}, the C_{sd}, the C_{gd}, and potentially the C_{gs}, reduce the accuracy of component measurements connected via the NLDMOS 10. For example, a low capacitance is suitable for (high-voltage) AC voltage applications such as data acquisition systems (e.g., ADAQ7768-1). Such systems may preferably work at higher input frequencies with good total harmonic distortion (THD).

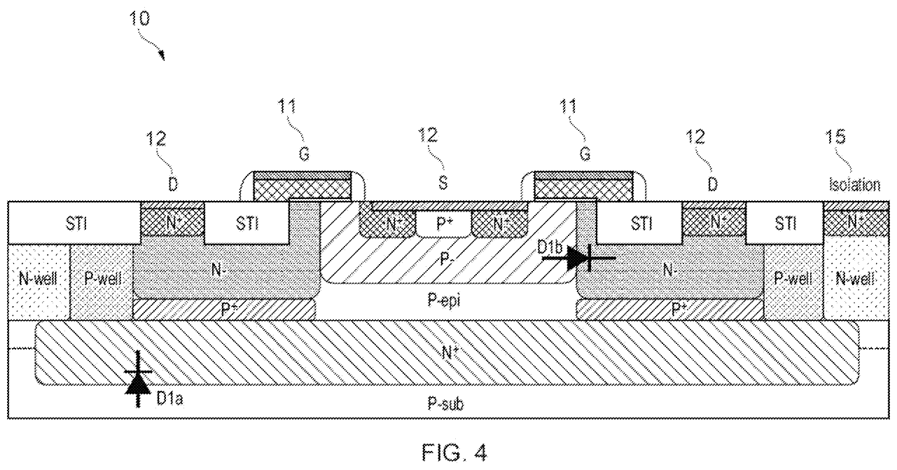

FIG. 4 shows an example of a semiconductor structure of an NLDMOS transistor, specifically an NLDMOS 10. The parasitic diodes D1a and D1b are shown in FIG. 4.

As shown in FIGS. 3a, 3b, and 4 the NLDMOS 10 is susceptible to leakage currents and capacitances which reduce the accuracy of component measurements connected via the NLDMOS 10, can limit the speed of high frequency AC components connected via the solid state switch, and reduce the power efficiency of the NLDMOS 10.

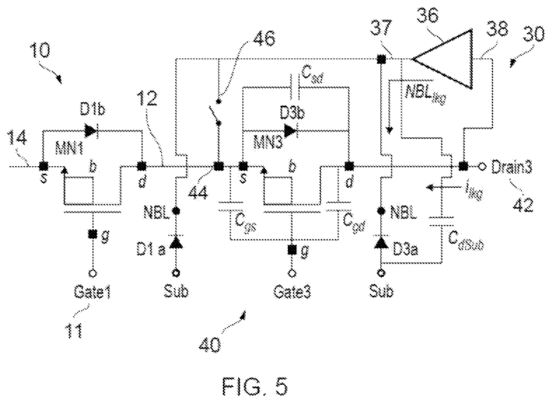

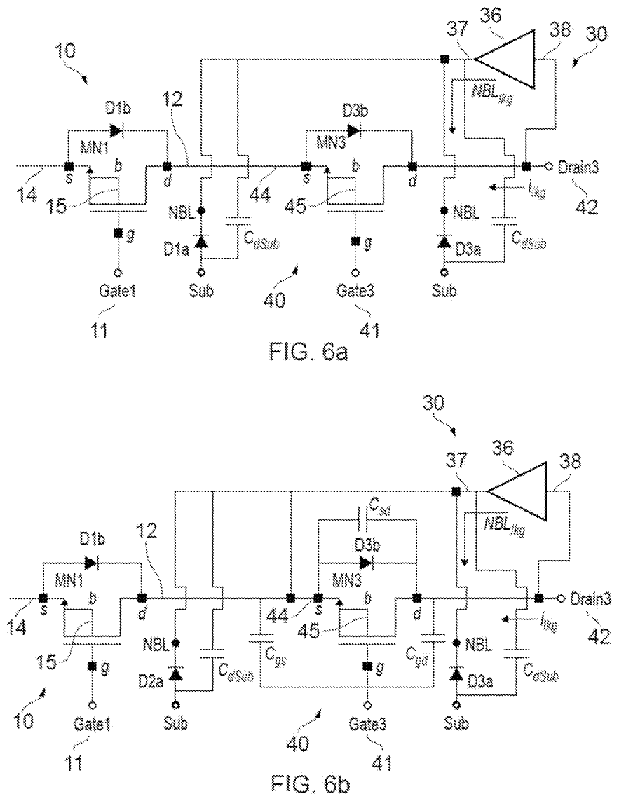

FIG. 5 shows a solid state switch comprising the first NLDMOS 10 (parasitic capacitances of the first NLDMOS 10 are not shown in FIG. 5 for clarity purposes, however, parasitic capacitances of the first NLDMOS 10 can be seen in FIGS. 6a and 6b) coupled in series to a circuit 30 comprising a second MOSFET 40 and a buffer 36. The circuit 30 connected to the first NLDMOS 10 isolates a parasitic capacitance (C_{dsub}, C_{sd}, C_{gd}, C_{gs}) of the first NLDMOS 10 from a voltage input 42 (i.e., drain terminal 42 of the second MOSFET 40) so as to reduce capacitance at the voltage input 42 of the solid state switch when compared to the drain terminal 12 of the first NLDMOS 10 without the circuit 30. The parasitic capacitance of the first NLDMOS 10 is therefore moved out of the input/output signal chain of the solid state switch (i.e., between source 14 of the first LDMOS 10 and drain 42 of the second MOSFET 40) and to the output 37 of the buffer 36. The circuit 30 may also reduce the leakage at the drain terminal 12 of the first NLDMOS 10 (e.g., by providing a 0V across the parasitic diodes D1a, D3a). The circuit 30 may reduce capacitance and reduce leakage at the first NLDMOS 10 when the voltage at the drain terminal 12 of the first NLDMOS 10 is greater than the voltage at the source 14 of the first NLDMOS 10.

As shown in FIG. 5, the second MOSFET 40 is in series with the first NLDMOS 10. The second MOSFET 40 has a gate terminal 41, a drain terminal 42, and a source terminal 44. A bulk 45 of the second MOSFET 40 is coupled to the source terminal 44 of the second MOSFET. The drain terminal 12 of the first NLDMOS 10 is connected to the source terminal 44 of the second MOSFET 40. The buffer 36 includes an output terminal 37; and an input terminal 38 coupled to the drain terminal 42 of the second MOSFET 40. Optionally, the circuit 30 comprises a switch 46 which is configured to couple the output 37 of the buffer 36 to the source of the second MOSFET 40 when the second MOSFET 40 is in an off-state (i.e., switched ‘OFF’).

A parasitic diode D3a of the second MOSFET 40 is formed between the substrate and an isolation layer, such as an N-type buried layer (NBL). The NBL is coupled to a NBL terminal, which may be accessible to a circuit designer. The output terminal 37 of the buffer 36 is coupled to the NBL terminal of the first NLDMOS 10 and the NBL terminal of the second MOSFET 40. This may be achieved by coupling the NBL terminal of the first and second MOSs 10, 40 to the output 37 of the buffer 36. A parasitic diode D3b of the second MOSFET 40 is formed between the source 44 and drain 42 of the second MOSFET 40. The parasitic diodes D3a and D3b of the second MOSFET 40 are formed between P-type and N-type material of the second MOSFET 40. The first NLDMOS 10 may be any type of MOS transistor. The second MOSFET 40 may be an LDMOS transistor or may be any other type of MOSFET.

FIG. 6a shows the solid state switch of FIG. 5 with a parasitic drain-substrate capacitor (C_{dsub}) of the first and second MOSs 10, 40 shown. The connections and parasitic components shown in FIG. 6a are the connections and the dominant parasitic components when the second MOSFET 40 is in an on-state (i.e., switched ‘ON’). During an on-state of the solid state switch, the first and second MOSs 10 and 40 can be switched ‘ON’ simultaneously by gate-drive circuitry.

When the second MOSFET 40 is in the on-state, the output 37 of the buffer 36 is coupled to the NBL (e.g. NBL terminal 15 of FIG. 4) of the first NLDMOS 10 (i.e., the anode of the parasitic diode D1a) and/or the NBL of the second MOSFET 40 (i.e., the anode of the parasitic diode D3a). This can beneficially isolate a parasitic capacitance of the first NLDMOS 10 from the drain terminal of the second MOSFET 40 so as to reduce capacitance (and leakage) at the drain terminal of the first NLDMOS 10. In other words, the parasitic capacitances of the solid state switch (i.e., the first and second MOSs) are not ‘seen’ by (i.e., do not interact with) a signal passing through the solid state switch.

If the first and second MOSs 10, 40 are in the on-state, the voltage difference between the source terminal 44 of the second MOSFET 40 and the drain terminal 42 of the second MOSFET 40 (i.e., across the parasitic diode D3b) is approximately 0V. The buffer 36 receives at its input 38 the voltage at the drain 42 of the second MOSFET 40 and approximately replicates the voltage at its output 37. There is a large voltage differential across the parasitic diode D1a, D3a, and the C_{dsub} of the second MOSFET 40. The capacitance of C_{dsub} of the first and second MOSFETs 10, 40 is no longer in the signal path from source terminal 14 of the first NLDMOS 10 to the drain terminal 42 of the second MOSFET 40 (and therefore the parasitic capacitances do not substantially interact with a signal passing through the solid state switch). Therefore, the parasitic capacitance of the first NLDMOS 10 is isolated and the negative side effects of the C_{dsub} of the first NLDMOS 10 are overcome, and the accuracy of component measurements connected via the solid state switch can be improved.

Optionally, the buffer 36 is a unitary gain buffer (UGB) 36 (e.g., an operational amplifier based buffer circuit with unitary gain). A UGB 36 provides a low impedance output and therefore can source or sink current at the output 37 of the UGB 36. Therefore, current leakage from D1a and D3a can (in theory) be eliminated, or at least greatly reduced. Therefore, an advantage of a UGB 36 is that leakage is reduced at the drain terminal of the first NLDMOS 10. A reduced leakage can result in improved power efficiency and accuracy of component measurements connected via the solid state switch.

FIG. 6b shows the solid state switch of FIG. 5 with the parasitic drain-substrate capacitor (C_{dsub}) of the first and second MOSs 10, 40, a parasitic source-drain capacitor (C_{sd}) of the second MOSFET 40, a parasitic gate-source capacitor (C_{gs}) of the second MOSFET 40, and a parasitic gate-drain capacitor (C_{gd}) of the second MOSFET 40 shown. The connections and parasitic components shown in FIG. 6b are the connections and the parasitic components when the second MOSFET 40 is in the off-state (i.e., switched ‘OFF’). During an off-state of the solid state switch, the first and second MOSs 10 and 40 can be switched ‘OFF’ simultaneously.

When the second MOSFET 40 is in the off-state, the circuit 30 is configured to couple the buffer 36 to be in parallel with the second MOSFET 40 between its source terminal 44 and drain terminal 42. The input 38 of the buffer 36 is coupled to the drain terminal 42 of the second MOSFET 40. The output 37 of the buffer 36 is coupled to the NBL terminal of the first NLDMOS 10 (i.e., the anode of the parasitic diode D1a), and/or the NBL terminal of the second MOSFET 40 (i.e., the anode of the parasitic diode D3a), and a node coupled (e.g., directly coupled) to the source terminal 44 of the second MOSFET 40 and the drain terminal 12 of the first NLDMOS 10.

If the first and second MOSs 10, 40 are in the off-state and the voltage at the drain terminal 42 of the second MOSFET 40 is greater than the voltage at the source terminal 14 of the first NLDMOS 10, then there is a large voltage differential between the source terminal 14 of the first NLDMOS 10 and the drain terminal 12 of the first NLDMOS 10 (i.e., across the parasitic diode D1b of the first NLDMOS 10). The voltage difference between the source terminal 44 of the second MOSFET 40 and the drain terminal 42 of the second MOSFET 40 (i.e., across the parasitic diode D3b) may be approximately 0V, due to the buffer 36. The buffer 36 receives at its input 38 the voltage at the drain terminal 42 of the second MOSFET 40 and approximately replicates the voltage at its output 37. There is a large voltage differential across the parasitic diode D1a, D3a, and the C_{dsub} of the second MOSFET 40. When the second MOSFET 40 is in the off-state the C_{sd} of the second MOSFET 40, the C_{gs} of the second MOSFET 40, the C_{gd} of the second MOSFET 40 are approximately equal to zero (because the gate voltage is approximately equal to the source voltage of the second MOSFET 40). The capacitance of C_{dsub} of the first and second MOSs 10, 40 is no longer on the signal path from the source terminal 14 of the first NLDMOS 10 to the drain terminal of the second MOSFET 40. Therefore, the negative side effects of the C_{dsub} of the first NLDMOS 10 are overcome, and the accuracy of component measurements made when connected via the solid state switch can be improved.

Optionally, the buffer 36 is a unitary gain buffer (UGB) 36 (e.g., an operational amplifier based buffer circuit with unitary gain). A UGB 36 provides a low impedance output and therefore can sink or source current at the output 37 of the UGB 36. When the second MOSFET 40 is in the off-state, the C_{gs} of the second MOSFET 40 is approximately equal to zero because there is no charge applied to the C_{gs} of the second MOSFET 40. Therefore, improved accuracy of component measurements connected via the solid state switch can be achieved. If the buffer 36 can match the output voltage to the input voltage, then current leakage from D1a and D3a can (in theory) be eliminated. A UGB 36 can beneficially provide a particularly low difference between the input and output voltages. Therefore, a UGB 36 can achieve improved accuracy of component current measurements due to low current leakage ‘seen’ by the components connected via the solid state switch. Additionally, if the buffer 36 (and optionally, gate drive circuitry configured to operate the gates of the first NLDMOS 10 and the second MOSFET 40 each) comprises an operational amplifier, then improved THD can be achieved.

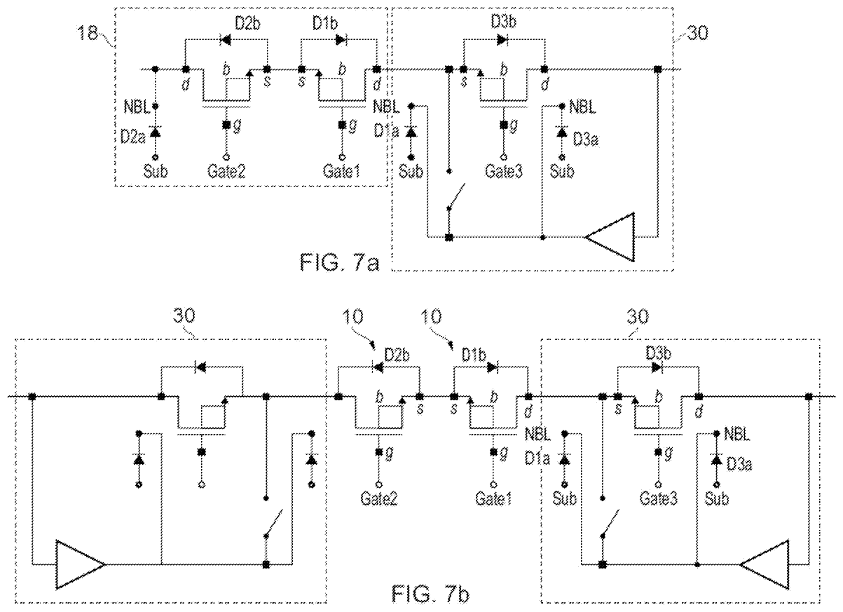

FIG. 7a shows a bi-directional solid state switch with a circuit 30 for capacitance (and leakage) reduction (which can be implemented in n-type or p-type components) on one terminal (also called unidirectional capacitance (and leakage) reduction). The circuit 30 (as described with reference to FIGS. 5, 6a, and 6b) can be coupled to the bi-directional solid state switch, such as, the bi-directional NLDMOS switch 18 of FIG. 2 to make a bi-directional solid state switch with unidirectional capacitance (and leakage) reduction (as shown in FIG. 7a). The circuit 30 coupled to the first NLDMOS 10 of FIG. 2 is suitable for reducing the capacitance (and leakage) when the voltage at the drain terminal 42 of the second MOSFET 40 is greater than the voltage at the drain terminal 22 of the second NLDMOS 20.

FIG. 7b shows a bi-directional switch with a circuit 30 for capacitance (and leakage) reduction (which can be implemented in n-type or p-type components) on two terminals (also called bi-directional capacitance (and leakage) reduction). A solid state switch may be a bi-directional solid state switch with bi-directional capacitance (and leakage) reduction. The bi-directional solid state switch can comprise two of the circuits 30 to reduce the capacitance (and leakage) of each of the first and second NLDMOS' 10, 20 in both current flow directions. As shown in FIG. 7b, the bi-directional solid state switch can be constructed by connecting the solid state switch of FIG. 5 in series with a second solid state switch (identical to the solid state switch of FIG. 5), by coupling the source's 14 of each first NLDMOS 10 together.

Alternatively, the bi-directional switch with a circuit 30 for capacitance (and leakage) reduction on two terminals may be reconfigured to use only a singular buffer (e.g., the buffer 36 of circuit 30) using a suitable switching arrangement to couple the output terminal of the buffer 36 to the isolation terminal of the third MOSFET and first MOSFET. The switching arrangement may comprise a first switch configured to couple the input terminal of the buffer 36 to either the drain terminal 42 of the second MOSFET 40 or the drain terminal of the fourth MOSFET. The switching arrangement may further comprise a second switch configured to couple the output terminal of the buffer 36 to either: the isolation terminal of the first and/or second MOSFET; or, the isolation terminal of the third and/or fourth MOSFET.

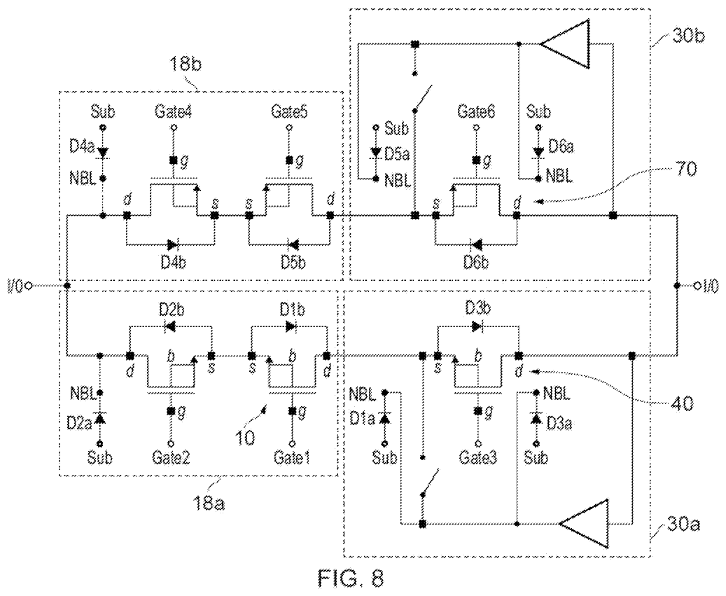

FIG. 8 shows a bi-directional solid state T-gate switch with unidirectional capacitance (and leakage) reduction. The bi-directional solid state T-gate switch with unidirectional capacitance (and leakage) reduction comprises an n-type bi-directional solid state switch with unidirectional capacitance (and leakage) reduction in parallel with a p-type bi-directional solid state switch with unidirectional capacitance (and leakage) reduction.

The n-type bi-directional solid state switch with unidirectional capacitance (and leakage) reduction comprises an n-type circuit 30a (such as circuit 30 of FIGS. 5, 6a, and 6b) coupled in series to an n-type bi-directional solid state switch 18a (such as, the bi-directional NLDMOS switch 18 of FIG. 2). The p-type bi-directional solid state switch with unidirectional capacitance (and leakage) reduction comprises a p-type circuit 30b (such as a p-type version of circuit 30 of FIGS. 5, 6a, and 6b, that is, the circuit 30 except the second MOSFET 40 of the circuit 30 is a p-type MOSFET 70) coupled in series to a p-type bi-directional solid state switch 18b (such as, a p-type version of the bi-directional NLDMOS switch 18 of FIG. 2).

Alternatively, the n-type bi-directional solid state switch 18a may be an n-type MOSFET switch, and the p-type bi-directional solid state switch 18b may be a p-type MOSFET switch.

The T-gate arrangement described with reference to FIG. 8 comprises two buffers: one in each of the n-type circuit 30a and the p-type circuit 30b. Alternatively, the bi-directional solid state T-gate switch with unidirectional capacitance (and leakage) reduction may be reconfigured to use only a singular buffer (e.g., the buffer 36 of circuit 30) using a suitable switching arrangement.

Alternatively, a solid state switch may be a bi-directional solid state T-gate switch with bi-directional capacitance (and leakage) reduction. The bi-directional solid state T-gate switch can comprise two of each of the n-type circuit 30a and p-type circuit 30b to reduce the capacitance (and leakage) in both current flow directions of each of the n-type bi-directional solid state switch 18a and p-type bi-directional solid state switch 18b.

Alternatively, the bi-directional solid state switches 18a and 18b may be any type of MOSFETs respectively.

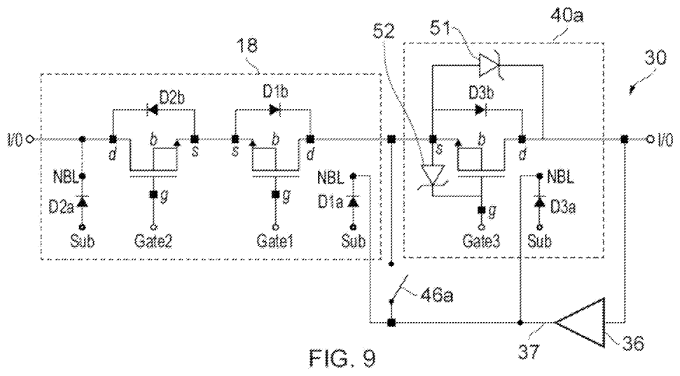

FIG. 9 shows a bi-directional high voltage (i.e. 10V or higher) solid state switch with low voltage (i.e., 5V or lower) unidirectional capacitance (and leakage) reduction (which can be implemented in n-type or p-type components). The bi-directional solid state switch with unidirectional capacitance (and leakage) reduction can comprise a circuit 30 (such as circuit 30 of FIGS. 5, 6a, and 6b) coupled in series to a bi-directional solid state switch 18 (such as, the bi-directional NLDMOS switch 18 of FIG. 2). The circuit 30 comprises an isolated low voltage MOSFET 40a which is functionally identical to the second MOSFET 40 of FIGS. 5, 6a, and 6b. The isolated low voltage MOSFET 40a enables unidirectional capacitance (and leakage) reduction for a high voltage solid state switch using low voltage components. Low voltage components may advantageously provide reduced area and power consumption in comparison to higher voltage components.

In addition, extra circuitry may protect the isolated low voltage MOSFET 40a from high voltage operation, i.e., the drain-source voltage of the isolated low voltage MOSFET 40a should not exceed the low voltage breakdown specified for the isolated low voltage MOSFET 40a. In addition, the gate-source voltage of the isolated low voltage MOSFET 40a should not exceed the low voltage breakdown specified for the isolated low voltage MOSFET 40a. This can optionally be achieved by including Zener diodes 51, 52 into the circuit 30. A first Zener diode 51 can be coupled in parallel with the isolated low voltage MOSFET 40a, i.e., between the source and drain of the isolated low voltage MOSFET 40a. A second Zener diode 52 can be coupled between the source and gate of the isolated low voltage MOSFET 40a.

Optionally, the circuit comprises a switch 46a which is configured to couple the output 37 of the buffer 36 to the source of the isolated low voltage MOSFET 40a when the isolated low voltage MOSFET 40a is in an off-state (i.e., switched ‘OFF’). When the isolated low voltage MOSFET 40a is configured to be in an on-state: the output 37 of the buffer 36 is not coupled to the source terminal of the isolated low voltage MOSFET 40a. The isolated low voltage MOSFET 40a is in an on-state when the output voltage of the buffer 36 is above the threshold voltage of the isolated low voltage MOSFET 40a but below the maximum voltage of the isolated low voltage MOSFET 40a (e.g., 5V for an isolated 5V MOSFET).

Alternatively, a solid state switch may be a bi-directional high voltage solid state switch with low voltage bi-directional capacitance (and leakage) reduction. The bi-directional high voltage solid state switch can comprise two of the circuits 30 to reduce the capacitance (and leakage) in both current flow directions when placed at either side of the bi-directional solid state switch 18.

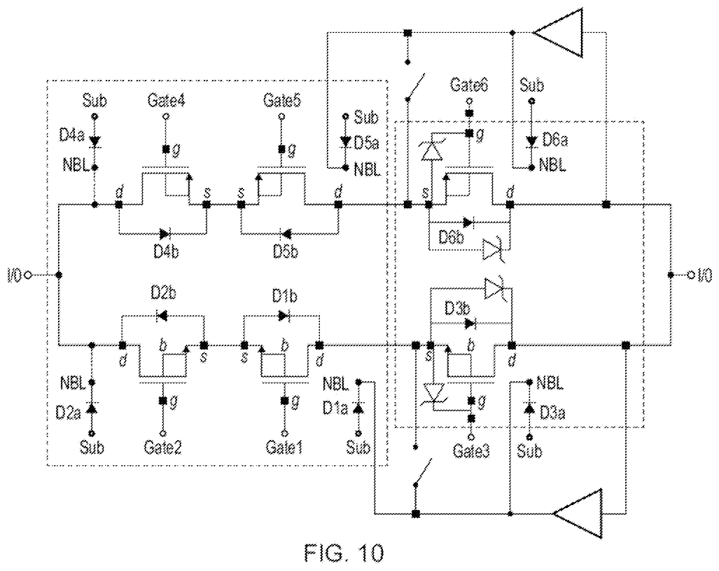

Alternatively, as shown in FIG. 10, the bi-directional high voltage solid state switch with low voltage unidirectional capacitance (and leakage) reduction may be implemented in a solid state T-gate switch, such as the bi-directional solid state T-gate switch with unidirectional capacitance (and leakage) reduction of FIG. 8. The bi-directional solid state T-gate switch with unidirectional capacitance (and leakage) reduction may comprise an n-type arrangement of a bi-directional high voltage solid state switch with low voltage unidirectional capacitance (and leakage) reduction corresponding to the solid state switch of FIG. 9, in parallel with, a p-type arrangement of a bi-directional high voltage solid state switch with low voltage unidirectional capacitance (and leakage) reduction corresponding to a p-type version of the solid state switch of FIG. 9.

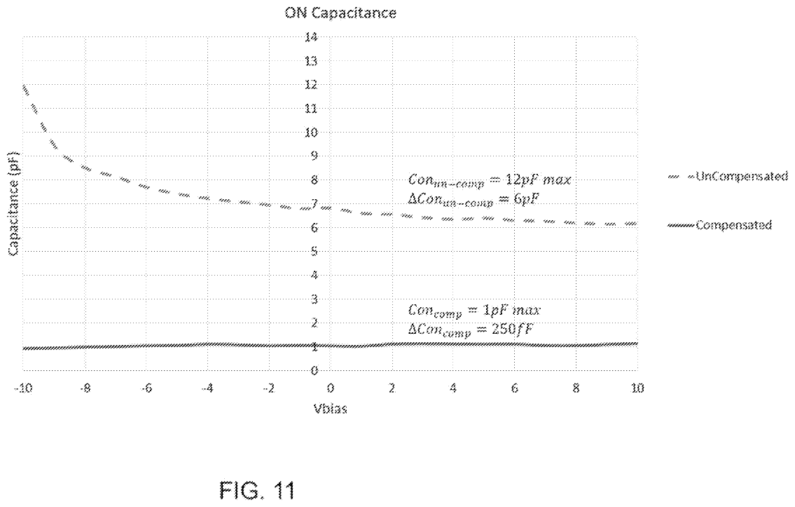

FIG. 11 shows a graph based on experimental results. The graph shows the reduction in the on-capacitance of a solid state switch for circuit in FIG. 7b.

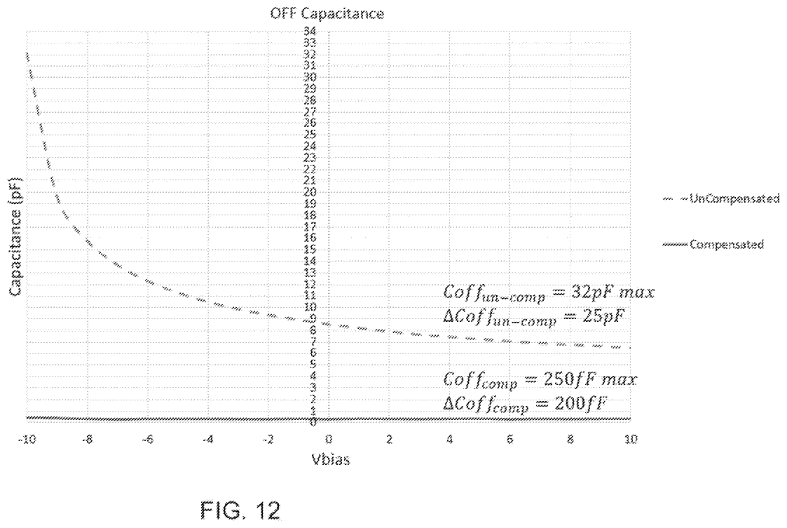

FIG. 12 shows a graph based on experimental results. The graph shows the reduction in the off-capacitance of a solid state switch for circuit in FIG. 7b.

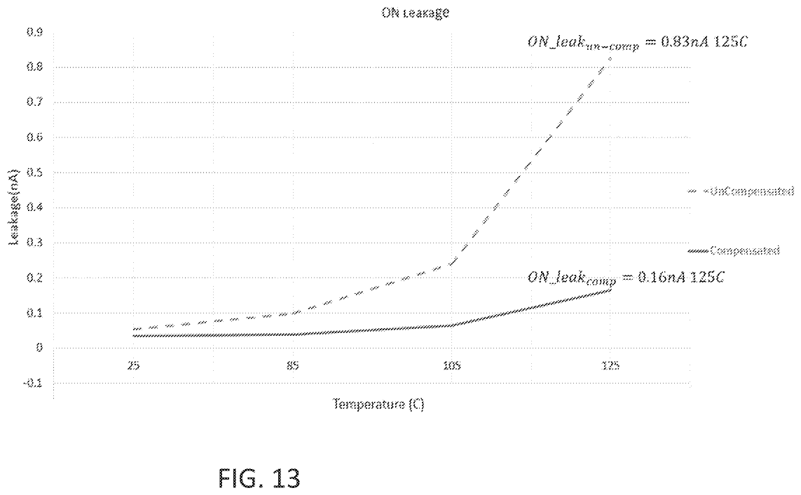

FIG. 13 shows a graph of an on-leakage in a solid state switch based on experimental results. The graph shows the reduction in the on-leakage of a solid state switch for circuit in FIG. 7b.

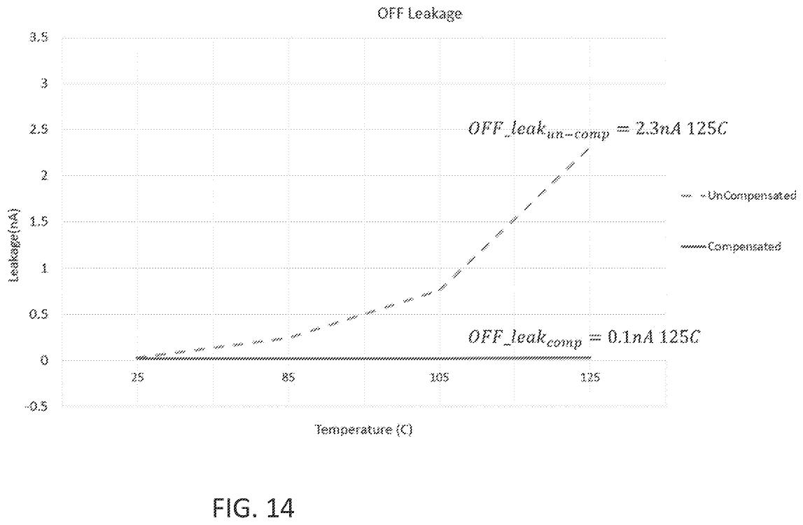

FIG. 14 shows a graph of an off-leakage in a solid state switch based on experimental results. The graph shows the reduction in the on-leakage of a solid state switch for circuit in FIG. 7b.

The values of any components herein may be changed depending on the application and/or designer choice.

For all of the above designs and circuits, it is possible to add additional components while still achieving the technical effects associated with each embodiment.

The switch 46 of FIG. 5 enables the benefits associated with FIG. 6a and FIG. 6b to be realised. Alternatively, the circuit 30 may only have the connections of FIG. 6a or FIG. 6b to achieve capacitance (and leakage) reduction when the solid state switch is either ‘ON’ or ‘OFF’, respectively.

Alternatively, the MOS devices herein may comprise an isolation terminal or may not comprise an isolation terminal (e.g. Silicon on Insulator (SOI) devices). The first MOSFET 10 can comprise an isolation terminal and the output terminal of the buffer 36 can be coupled only to the isolation terminal of the first MOSFET 10. The second MOSFET 40 can comprise an isolation terminal and the output terminal of the buffer 36 can be coupled only to the isolation terminal of the second MOSFET 40. Alternatively, the output terminal of the buffer 36 can be coupled to the isolation terminal of the first MOSFET 10 and the isolation terminal of the second MOSFET 40. Alternatively, the output terminal of the buffer may only be coupled to the source terminal of the second MOSFET when the first MOSFET is in the off-state (e.g., if neither MOS devices 10, 40 comprise an isolation terminal). If the buffer output terminal is coupled to an isolation terminal of the second MOSFET alone (or the buffer output terminal is coupled to only the source terminal of the second MOSFET when the first MOSFET is in the off-state), then a reduction in the OFF capacitance/leakage can be achieved. If the buffer output terminal is coupled to an isolation terminal of the first MOSFET alone, then a reduction in the capacitance/leakage can be achieved. If the buffer output terminal is coupled to an isolation terminal of the first and second MOSFET, then a greater reduction in the capacitance/leakage can be achieved.

The FIGS. 1-7, and 9, are shown for n-type devices, however, the teachings can be readily applied to p-type devices by a person skilled in the art, and vice versa.

The output 37 of the buffer 36 is shown to be coupled to the isolation terminals of both the first MOSFET 10 and the second MOSFET 40 in FIGS. 5-10. Alternatively, the output 37 of the buffer 36 may only be coupled to the isolation terminal of the first MOSFET 10 in order to achieve reduced capacitance (and leakage), for example, if the second MOSFET 40 has different leakage/capacitance characteristics to the first MOSFET 10. The above applies equally to the other MOSFETs in a similar arrangement, e.g., the third and fourth MOSs of FIGS. 7b, 8, and 10.

The second MOSFET 40 may be any type of MOSFET design. The terminal of the gate 41 of the second MOSFET 40 may be a gate terminal. The terminal of the drain 42 of the second MOSFET 40 may be a drain terminal. The terminal of the source 44 of the second MOSFET 40 may be a source terminal. The second MOSFET 40 may not comprise a bulk coupled to the source of the second MOSFET 40.

When a MOSFET is an n-type MOSFET, it may comprise a buried layer which is an NBL. Alternatively, when a MOSFET is an p-type MOSFET, it may comprise a buried layer which is a p-type buried layer (PBL). The term buried layer may be used herein for n or p-type high-voltage MOSs. The term isolation layer may be used herein for n or p-type MOSs.

When reference is made to a drain, source, gate, bulk, buried layer, isolation layer or other input/output of a component, this may include a drain terminal, source terminal, gate terminal, bulk terminal, buried layer terminal, isolation terminal or other input/output terminal of a component, respectively (and vice versa).

The buffer 36 may be a unity gain buffer in FIGS. 5-10. The unity gain buffer may comprise an operational amplifier to reduce leakage and capacitance at the drain of the connected MOS (e.g., the first MOSFET 10 in FIGS. 5-10). The operational amplifier may be one of: a continuous time auto-zero operational amplifier; or a continuous time ping-pong auto zero operational amplifier, to achieve a low voltage difference across the buffer 36.

Alternatively, the buffer 36 may be a voltage follower circuit. The voltage follower circuit can reduce capacitance at the drain of the connected MOSFET (e.g., the first MOSFET 10 in FIGS. 5-10). The voltage follower circuit is simpler to implement and reduces circuit complexity. The voltage follower circuit is usually an open loop or feedforward type circuit.

Alternatively, the buffer 36 may be a cascade complementary source follower (CCSF). The CCSF can reduce capacitance at the drain of the connected MOSFET (e.g., the first MOSFET 10 in FIGS. 5-10). The CCSF is simpler to implement and reduces circuit complexity. The CCSF can achieve near zero voltage drop across the CCSF, although, this may vary with temperature and silicon processes. Alternatively, the buffer 36 may be any other implementation of a source follower type circuit or buffer.

### General

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.”

The words “coupled” or “connected”, as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list.

It is to be understood that one or more features from one or more of the above-described embodiments may be combined with one or more features of one or more other ones of the above-described embodiments, so as to form further embodiments which are within the scope of the appended claims.

1. A solid state switch, comprising:
a first metal-oxide-semiconductor field-effect transistor, MOSFET, comprising: a drain terminal, a source terminal, and a gate terminal, and configured to be switched between an on-state and an off-state;
a second MOSFET in series with the first MOSFET, wherein the second MOSFET has a gate terminal, a drain terminal, and a source terminal, and wherein the drain terminal of the first MOSFET is connected to the source terminal of the second MOSFET; and,
a buffer comprising: an output terminal and an input terminal coupled to the drain terminal of the second MOSFET, wherein at least one of:
the first MOSFET comprises an isolation terminal and the output terminal of the buffer is coupled to the isolation terminal of the first MOSFET; and
the second MOSFET comprises an isolation terminal and the output terminal of the buffer is coupled to the isolation terminal of the second MOSFET.

2. The solid state switch of claim 1, wherein the second MOSFET and the buffer form a circuit configured to isolate a parasitic capacitance of the first MOSFET from the second terminal of the second transistor so as to reduce capacitance at the drain terminal of the first MOSFET.

3. The solid state switch of claim 1, wherein the buffer is: a unity gain buffer, UGB; a voltage follower; or a cascade complementary source follower.

4. The solid state switch of claim 1, wherein the buffer is a UGB so as to reduce leakage at the drain terminal of the first MOSFET.

5. The solid state switch of claim 1, wherein the first MOSFET is a high voltage MOSFET, and the second MOSFET is an isolated 5V MOSFET.

6. The solid state switch of claim 1, wherein, when the first MOSFET is in the off-state, the buffer is configured to be coupled in parallel with the second MOSFET between its drain and source terminals.

7. The solid state switch of claim 1, wherein, when the first MOSFET is in the on-state, the output terminal of the buffer is further coupled to the gate terminal of the second MOSFET so as to latch the second MOSFET in an on-state.

8. The solid state switch of claim 1, further comprising a substrate layer, wherein a parasitic diode of the first MOSFET is between the substrate layer and the isolation layer of the first MOSFET, and/or wherein a parasitic diode of the second MOSFET is between the substrate layer and the isolation layer of the second MOSFET.

9. The solid state switch of claim 1, wherein the first and/or second MOSFET is a diffusion MOSFET, DMOS.

10. The solid state switch of claim 1, wherein the first and/or second MOSFET is a Lateral Double-Diffusion MOSFET, LDMOS.

11. The solid state switch of claim 1, wherein the first MOSFET is a first DMOS, wherein the solid state switch further comprises a bi-directional DMOS switch comprising the first DMOS and a second DMOS, wherein the second DMOS comprises a gate terminal, a drain terminal, and a source terminal, wherein the source terminal of the second DMOS is coupled to the source terminal of the first DMOS.

12. The solid state switch of claim 11, wherein the bi-directional DMOS switch is a bi-directional Lateral Double-Diffusion MOSFET, LDMOS, switch, wherein the first DMOS transistor is an LDMOS and the second DMOS transistor is an LDMOS.

13. The solid state switch of claim 11, wherein the solid state switch is a T-gate switch comprising the first MOSFET in parallel with a first-type DMOS, wherein the first MOSFET is a second-type DMOS, wherein the first-type is n-type or p-type, wherein the second-type is p-type or n-type, wherein the first type is different to the second type.

14. The solid state switch of claim 11, wherein the solid state switch further comprises:
a third MOSFET, wherein the third MOSFET is at least one of the second DMOS and the first-type DMOS; and,
a fourth MOSFET in series with the third MOSFET, wherein the fourth MOSFET has a gate terminal, a drain terminal, and a source terminal, wherein the drain terminal of the third MOSFET is connected to the source terminal of the fourth MOSFET, wherein at least one of:
the third MOSFET comprises an isolation terminal and the output terminal of the buffer is coupled to the isolation terminal of the third MOSFET; and,
the fourth MOSFET comprises an isolation terminal and the output terminal of the buffer is coupled to the isolation terminal of the fourth MOSFET.

15. The solid state switch of claim 11, wherein the buffer is a first buffer, and the solid state switch further comprises:
a third MOSFET, wherein the third MOSFET is at least one of the second DMOS and the first-type DMOS;
a fourth MOSFET in series with the third MOSFET, wherein the fourth MOSFET has an isolation terminal, a gate terminal, a drain terminal, and a source terminal, wherein the drain terminal of the third MOSFET is connected to the source terminal of the fourth MOSFET; and,
a second buffer comprising: an output terminal; and, an input terminal coupled to the drain terminal of the fourth MOSFET, wherein at least one of:
the third MOSFET comprises an isolation terminal and the output terminal of the second buffer is coupled to the isolation terminal of the third MOSFET; and,
the fourth MOSFET comprises an isolation terminal and the output terminal of the second buffer is coupled to the isolation terminal of the fourth MOSFET.

16. The solid state switch of claim 14, wherein at least one of:
a parasitic diode of the third MOSFET is between the substrate layer and the isolation layer of the third MOSFET; and,
a parasitic diode of the fourth MOSFET is between the substrate layer and the isolation layer of the fourth MOSFET.

17. The solid state switch of claim 14, wherein the fourth MOSFET is a diffusion MOSFET, DMOS.

18. The solid state switch of claim 14, wherein the third and/or fourth MOSFET is a Lateral Double-Diffusion MOSFET, LDMOS.

19. A solid state switch, comprising:
a first metal-oxide semiconductor field-effect transistor, MOSFET, comprising: a drain terminal, a source terminal, and a gate terminal, and configured to be switched between an on-state and an off-state;
a second MOSFET in series with the first MOSFET, wherein the second MOSFET has a gate terminal, a drain terminal, and a source terminal, and wherein the drain terminal of the first MOSFET is coupled to the source terminal of the second MOSFET; and
a buffer comprising:
an output terminal coupled to the source terminal of the second MOSFET when the first MOSFET is in the off-state; and
an input terminal coupled to the drain terminal of the second MOSFET.

20. A circuit comprising:
a MOSFET, wherein the MOSFET has a gate terminal, a drain terminal, and a source terminal; and,
a buffer comprising: an output terminal; and an input terminal coupled to the drain terminal of the MOSFET, wherein the MOSFET is configured to be coupled to another MOSFET in series such that the source terminal of the MOSFET is coupled to the drain terminal of the other MOSFET, wherein at least one of:
the output terminal of the buffer is configured to be coupled to an isolation terminal of the other MOSFET; and
the MOSFET comprises an isolation terminal and the output terminal of the buffer is coupled to the isolation terminal of the MOSFET.
